(19) United States
(12) Patent Application Publication
(10) Pub. No.: US 2022/0214244 A1
(43) Pub. Date: Jul. 7, 2022

(54) SYSTEMS AND METHODS FOR ASSESSING STRUCTURAL HEALTH

(71) Applicant: SIKORSKY AIRCRAFT CORPORATION, Stratford, CT (US)

(72) Inventors: Matthew HARRIGAN, Horseheads, NY (US); Theodore MEYER, Pavilion, NY (US); Darryl M. TONI, Clinton, CT (US); Avinash SARLASHKAR, Pittsford, NY (US)

(21) Appl. No.: 16/757,212

(22) PCT Filed: Oct. 18, 2017
(86) PCT No.: PCT/US2017/057189

§ 371 Date: Apr. 17, 2020

(51) Int. Cl. G01M 5/00; B64D 45/00

(52) U.S. Cl. CPC G01M 5/0033; B64D 2045/0085; B64D 45/00

(57) ABSTRACT

A method of determining structural health of an assembly includes determining a Margin of Safety (MS_{H}) value for at least one of a plurality of components in the assembly when the assembly is healthy. The method includes determining if damage to the assembly has occurred. If damage to the assembly has occurred, the method includes determining a Margin of Safety (MS_{D}) value for at least one of the plurality of components in the assembly when the assembly is damaged. The method includes determining a Structural Health Index (SHI) of the assembly based on the MS_{D} value for the at least one undamaged component.

### CROSS REFERENCE TO RELATED APPLICATIONS

This application is a National Stage application of PCT/US2017/057189 filed Oct. 18, 2017, the entire contents of which are hereby incorporated by reference.

### STATEMENT REGARDING FEDERALLY SPONSORED RESEARCH OR DEVELOPMENT

This invention was made with government support under contract number W911W6-13-2-0006 awarded by the United States Army. The government has certain rights in the invention.

### BACKGROUND OF THE INVENTION

### Field of the Invention

The present disclosure relates to aircraft health monitoring, and more particularly to assessing the structural health of airframes in rotorcraft.

### Description of Related Art

Aerospace vehicles, such as airplanes and helicopters, may face sources of potential damage such as from flight loads, ground loads, the external environment and non-deterministic sources such as foreign object debris (FOD) or other items that can cause damage by impacting or striking the vehicle. The damage sources can stress and damage the structure of the vehicle, leading to repairs or safety concerns.

Traditional approaches to such potential damage is to replace or repair an aircraft assembly or a portion thereof once damage has been incurred. Replacement or repair just on the appearance of damage, without any assessment of how the structural integrity or flight safety may have been effected, can result in unnecessary significant costs, negatively impact aircraft availability, and add significant weight. This approach typically does not provide information relating to the overall structural health and/or flight safety for the airframe structural assembly. Therefore, out of an abundance of caution, a traditional approach may require that components or entire assemblies be repaired or replaced, even though the assembly may be able to perform missions without repair/replacement.

Such traditional methods and systems have generally been considered satisfactory for their intended purpose. However, there is still a need in the art for improved systems and methods assessing the overall structural health of an airframe structural assembly so as to eliminate unnecessary inspection and repairs and thereby increase availability. The present disclosure provides a solution for this need.

### SUMMARY OF THE INVENTION

A method of determining structural health of an assembly includes determining a Margin of Safety (MS_{H}) value for at least one of a plurality of components in the assembly when the assembly is healthy. The method includes determining if damage to the assembly has occurred. If damage to the assembly has occurred, the method includes determining a Margin of Safety (MS_{D}) value for at least one of the plurality of components in the assembly when the assembly is damaged. The method includes determining a Structural Health Index (SHI) of the assembly based on the MS_{D} value for the at least one undamaged component.

In some embodiments, the assembly can be a composite section of a rotorcraft airframe.

In accordance with some embodiments, determining the MS_{H} value for the at least one of the plurality of components includes comparing an allowable load for the at least one of the plurality of components to the applied load for the at least one of the plurality of components, wherein the applied load is determined through the use of an finite element analysis (FEA) model. Determining the MS_{D} value for the at least one undamaged component can include scaling its MS_{H} value based on increased loads due to the load redistribution with the following equation:

$$M {S}_{D} = ( M {S}_{H} + 1 ) \frac{{L}_{H}}{{L}_{D}} - 1$$

where L_{H} is a baseline load on the undamaged component before the load redistribution, and where L_{D} is a post-damage load on the at least one undamaged component after the load redistribution. Determining the post-damage load (L_{D}) for the at least one undamaged component can include considering a plurality of load cases for each undamaged component and generating a load envelope for each undamaged component using a plurality of baseline loads (L_{H}) acting on the undamaged component before the load redistribution. Generating the load envelope for each undamaged component can include expanding the load envelope using pre-determined rules to generate a broadened load envelope.

In some embodiments, the method includes determining the L_{D} for the at least one undamaged component by using a FEA model that reattributes a load that would have been carried by one or more of the damaged components to at least one of the undamaged components. The method can include re-determining the L_{D} for one or more of the undamaged components when one or more of the initial MS_{D} values for at least one other undamaged component is negative to generate at least one updated MS_{D} value based on the re-determined L_{D}. Re-determining the L_{D} can include using a FEA model that reattributes a load that would have been carried by one or more of the damaged components and one or more of the undamaged components having negative initial MS_{D} values to at least one of the undamaged components that had positive initial MS_{D} values.

It is contemplated that determining if damage to at least one of the plurality of components has occurred can include receiving a strain measurement from a sensor coupled to at least one of the plurality of components of the assembly. Determining if damage to at least one of the plurality of components has occurred can include visually inspecting at least one of the plurality of components.

In some embodiments, the method includes displaying a repair indicator on a graphical user interface (GUI) if the SHI exceeds a pre-determined threshold. The method can include continuously updating and displaying a status indicative of the SHI on a GUI. Determining the SHI of the assembly can include determining a component contribution parameter for at least one component of the assembly based on the MS_{D} value for that component. Determining the SHI of the assembly can include summing the component contribution parameters for the components of the assembly. Determining the SHI of the assembly can include determining an adjustment factor by comparing the sum of the component contribution parameters for the components of the assembly to pre-determined reference values. Determining the SHI of the assembly can include determining an adjusted Margin of Safety (MS_{A}) for the assembly by subtracting the adjustment factor from the minimum positive MS_{D} value for the components of the assembly. Determining the SHI of the assembly can include comparing the adjusted MS_{A} for the assembly to pre-determined reference values.

In accordance with another aspect, a structural health assessment system for a multi-load-path assembly includes a plurality of assembly components. At least one sensor is operatively connected to at least one of the plurality of components to capture damage-indicating data for at least one of the plurality of assembly components. A processor is in operative communication with at least one of the sensors to receive damage-indicating data therefrom. A memory is in operative communication with the processor having program instructions for determining structural health of an assembly. The program instructions being executable by the processor to perform the method as described above.

The system can include a GUI operatively connected to the processor to receive data therefrom. The GUI can display a repair indicator if the SHI exceeds a pre-determined threshold. The GUI can continuously display a status indicative of the SHI based on continuously updated real-time data from the processor. The plurality of assembly components can together form at least one of a cabin section assembly, a tail pylon assembly, a cockpit section assembly, a nose section assembly, or the like.

These and other features of the systems and methods of the subject disclosure will become more readily apparent to those skilled in the art from the following detailed description of the preferred embodiments taken in conjunction with the drawings.

### BRIEF DESCRIPTION OF THE DRAWINGS

So that those skilled in the art to which the subject disclosure appertains will readily understand how to make and use the devices and methods of the subject disclosure without undue experimentation, embodiments thereof will be described in detail herein below with reference to certain figures, wherein:

FIG. 1 is a schematic view of an exemplary rotorcraft having a structural health assessment system constructed in accordance with embodiments of the present disclosure, showing the structural health assessment system with sensors that send data from components of interest for assessing the structural health of an aircraft assembly;

FIG. 2 is a schematic depiction of an FEA model in accordance with embodiments of the present disclosure, showing how the structural health in the extending tail pylon assembly of FIG. 1 would be assessed; and

FIG. 3 illustrates a process flow in accordance with embodiments of the present disclosure assessing structural health in an aircraft assembly using the structural health assessment system of FIG. 1.

### DETAILED DESCRIPTION OF THE PREFERRED EMBODIMENTS

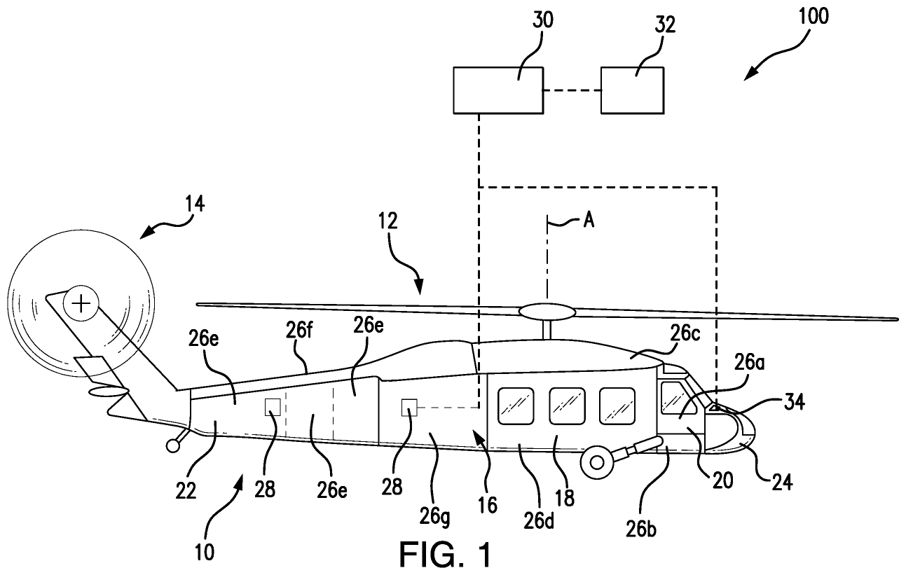

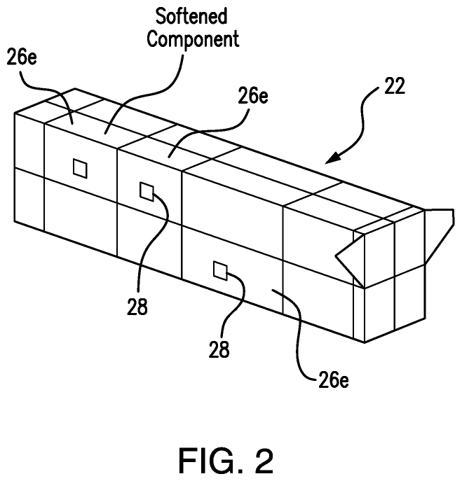

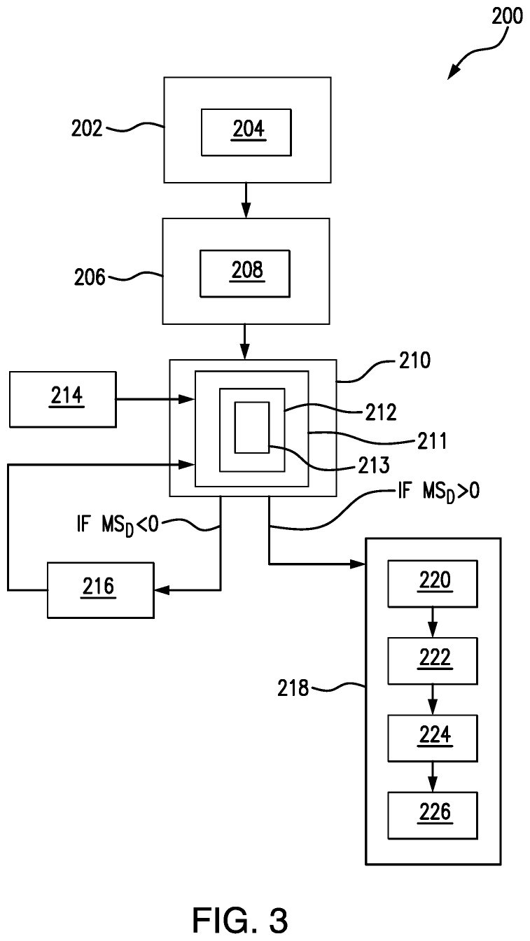

Reference will now be made to the drawings wherein like reference numerals identify similar structural features or aspects of the subject disclosure. For purposes of explanation and illustration, and not limitation, a partial view of an exemplary embodiment of a structural health assessment system for an assembly, e.g. an aircraft assembly, in accordance with the disclosure is shown in FIG. 1 and is designated generally by reference character 100. Other embodiments of structural health assessment systems and methods in accordance with the disclosure, or aspects thereof, are provided in FIGS. 2-3, as will be described. The systems and methods described herein can be used to assess the structural health of rotorcraft airframes, however the invention is not limited to rotorcraft airframes or to aircraft in general.

Embodiments described herein provide systems and methods for assessing structural health in an aircraft assembly by determining a Structural Health Index (SHI) that describes the overall health condition for a redundant, e.g. multi-load-path, damage tolerant, airframe structural assembly. The SHI describes the overall health condition for the airframe structural assembly and provides actionable information for maintenance decisions that reflects the overall damage state and fitness for service of the airframe.

Referring to FIG. 1, a schematic rotorcraft 10 is shown. Rotorcraft 10 includes a main rotor system 12 and an anti-torque system, for example, a tail rotor system 14. Main rotor system 12 is supported for rotation about a main rotor axis A by an airframe 16 of rotorcraft 10. Tail rotor system 14 is supported by a longitudinally extending tail pylon assembly 22 of airframe 16. Airframe 16 is an assembly that includes a number of airframe sub-assemblies, e.g., a tail pylon assembly 22, cabin section assembly 18, cockpit section assembly 20, nose section assembly 24, wing assembly, or the like. These sub-assemblies can be made up of one or more aircraft assembly components 26a-26g. It is contemplated that the components making up the aircraft assembly can be made from composite or metallic material.

With reference now to FIGS. 1 and 2, a structural health assessment system 100 used to assess the SHI of an aircraft assembly, e.g. a tail pylon assembly 22, cabin assembly 18, cockpit assembly 20, nose assembly 24, or the like, includes a plurality of aircraft assembly components 26a-26g. Those skilled in the art will readily appreciate that while aircraft assembly components 26a-26g are labeled and shown in FIG. 1, it is contemplated that other aircraft assembly components, either not shown or not labeled, can be included. A sensor 28 is operatively connected to aircraft component 26g to capture damage-indicating data for aircraft component 26g, e.g. load or strain data, or piezo-sensor-based damage characterization. Another sensor 28 is operatively connected to aircraft component 26e to capture damage-indicating data for aircraft component 26e, e.g. a component of tail pylon 22. As shown by FIGS. 1 and 2, tail pylon assembly 22 can have a number of components 26e, one or all of them can have an associated sensor 28. It is contemplated that more than one sensor 28 can be used for a given aircraft component and that other aircraft components, e.g. 26a, 26b, 26c, 26d, and 26f, can also include respective sensors.

As shown in FIG. 1, a processor 30 is in operative communication with at least one of the sensors to receive damage-indicating data therefrom. A memory 32 is in operative communication with the processor 30 having program instructions for determining structural health of an aircraft assembly. The program instructions are executable by the processor 30 to perform the method as will be described below to determine a SHI. The processor 30 and the memory 32 are shown remote from the rotorcraft 10, however, it is contemplated that structural health assessment system 100 may perform direct or virtual monitoring of aircraft structural loads in real-time onboard or remote to the aircraft. System 100 remote to aircraft can include an off-board system at a ground station used after the aircraft has landed, and/or an off-board system connected to the aircraft via satellite link in real time to send data from the aircraft to a ground station.

The SHI can be a numerical indicator ranging from 0.0 to 1.0. For example, a SHI of 0.0 means healthy, while 1.0 indicates need for repair. Thresholds from 0.0 to 1.0 can be specified to prompt various actions such as watch, warning and repair. The SHI can be determined for each major section or zone, e.g. cabin, tail cone, etc., of the redundant, damage tolerant, composite airframe assembly based on combining margin of safety for each constituent component. The SHI indicates whether a need exists to repair based on predicted structural load carrying capability. The SHI is determined by the method described below with respect to FIG. 3.

As shown by the schematic finite element analysis (FEA) model in FIG. 2, the SHI assessment takes into account any damaged component by removing it from the SHI analysis and re-distributing the load in a given scenario on the remaining undamaged components. FIG. 2 is a schematic representation of an FEA model of tail pylon assembly 22 where, as an example, a damaged one of components 26e is pointed out as “softened” for the analysis, e.g. the FEA will assume that the amount of load carried by the “softened” component will be zero and the load will be appropriately redistributed to the un-damaged components. In that way, the method 200, described below, can be used to determine the structural health of the tail pylon assembly as a whole based on the structural health of the un-damaged components.

With continued reference to FIG. 1, the system 100 can include a graphical user interface (GUI) 34 operatively connected to the processor 30 to receive data therefrom. The GUI 34 is shown schematically in the nose 24 of the aircraft 10. It is contemplated, however, that GUI 34 can be located in a variety of locations throughout aircraft 10 or can be off-board of the aircraft 10. The GUI 34 displays a repair indicator if the SHI for a given assembly exceeds a pre-determined threshold. The GUI 34 continuously displays a status indicative of the SHI based on continuously updated real-time data from the processor 30.

In view of the above, the system 100 and elements therein illustrated in FIG. 1 (and the other figures) may take many different forms and include multiple and/or alternate components and facilities. That is, while aircraft 10 is shown in FIG. 1, the components illustrated in FIG. 1 and the other Figures are not intended to be limiting. Indeed, additional or alternative components and/or implementations may be used. For instance, aircraft assemblies, their components and the sensors may include and/or employ any number and combination of sensors, computing devices, and networks utilizing various communication technologies that enable system 100 to perform the method of assessing structural health, as further described with respect to FIG. 3.

As shown in FIG. 3, a method 200 of determining structural health of an aircraft assembly, e.g. a tail pylon assembly 22, cabin assembly 18, cockpit assembly 20, nose assembly 24, includes determining a Margin of Safety (MS_{H}) value for at least one of a plurality of components, e.g. components 26a-26e, in the aircraft assembly, e.g. when aircraft assembly is healthy, as shown schematically by box 202. Determining the MS_{H} value for at least one of the plurality of components (202) includes referencing pre-determined MS_{H} values for a given scenario, as shown schematically by box 204. The pre-determined MS_{H} value is calculated by comparing the allowable load to the applied load as shown by the following equation:

$$M {S}_{H} = \frac{Allowable Load}{Applied Load} - 1 \qquad Equation 1$$

The Allowable Load is a conservative estimate of the failure load of the component when healthy and typically remains constant for a given healthy component. The Applied Load is the load acting on the component for some specific load condition in the operating envelope, also known as a limit load, and is determined through the use of a FEA model.

The method 200 includes determining if damage to at least one of the plurality of components has occurred, as shown schematically by box 206. Determining if damage to at least one of the plurality of components has occurred includes receiving a strain measurement from a sensor, e.g. sensor 28, coupled to at least one of the plurality of components of the aircraft assembly to determine changes in the strain pattern, as shown schematically by box 208. In some configurations, determining if damage to one of the plurality of components has occurred includes visually or ultrasonically inspecting at least one of the plurality of components, and/or receiving data from other structural health monitoring systems (either strain-based or non strain-based) designed to localize damage on structures, or the like, also shown schematically by box 208. As shown in FIG. 2, when a component incurs damage, the structural change is represented in the FEA model by softening (increased compliance) of the finite elements representing the damaged component. In a redundant (multi-load-path) structure, load that would have been carried by the now damaged component is redistributed to its healthy neighbors. Since applied load affects the margin of safety at the component level, the margin of safety must be recomputed for undamaged neighbors while accounting for potentially increased load due to the damage to the other component(s).

If damage to at least one of the plurality of components has occurred, the method includes determining a Margin of Safety (MS_{D}) value for at least one undamaged component in the assembly when the assembly is damaged based on a post-damage applied load (L_{D}) on the at least one undamaged component after load redistribution in the assembly, as shown schematically by box 210.

The method 200 includes determining a plurality of post-damage applied loads (L_{D}) for each undamaged component to account for multiple load cases by using a FEA model that reattributes a load that would have been carried by one or more of the damaged components to the at least one undamaged component, as shown schematically by box 214. The FEA determines a given post-damage applied load (L_{D}) for each of a plurality of load cases, e.g. several hundred or more load cases for a given undamaged component.

Determining the MS_{D} value for at least one undamaged component includes considering a plurality of load cases for each undamaged component and generating an MS_{D} value based on the smallest ratio of a baseline load (L_{H}) on the undamaged component before the load redistribution to post-damage applied load (L_{D}), as shown schematically by box 211. Determining the MS_{D} value for a given undamaged component is done by using the following equation:

$$M {S}_{D} = ( M {S}_{H} + 1 ) \frac{{L}_{H}}{{L}_{D}} - 1 \qquad Equation 2$$

where L_{H} is an applied load on the undamaged component before the load redistribution for the given load case. Essentially, Equation 2 scales MS_{H} based on the extent to which the loads are outside the bounds of what the component was originally designed to sustain for a given load case.

With continued reference to FIG. 3, considering a plurality of load cases for each undamaged component includes generating a load envelope for each undamaged component based on a set of applied loads (L_{H}) for each design load case of a given undamaged component before the load redistribution. Those skilled in the art will readily appreciate that the set of loads (L_{H}) can be used to develop a bounding envelope encompassing all load values (L_{H}) experienced by the undamaged component. Such a bounding load envelope can be one dimensional or multi-dimensional depending on the number of loads acting on the undamaged component. Load cases with L_{D} values within the load envelope are considered to have the margin of safety no less than MS_{H}. Load cases with L_{D} values outside of the load envelope may still have a positive margin. The L_{D} value farthest outside of the load envelope is used to determine the MS_{D} value for the component, also indicated schematically by box 212. A load vector for L_{D} intersecting with the load envelop defines L_{H} in Equation 2.

It is also contemplated that a plurality of MS_{D} values for a given component can be calculated using Equation 2 and the pre- and post-distribution loads (L_{H} and L_{D}) associated with the plurality of load cases. In that instance, the worst case MS_{D} value for the component can be used for the SHI analysis discussed below.

With continued reference to FIG. 3, generating the load envelope for each undamaged component includes expanding the load envelope using pre-determined rules, as indicated by box 213. This tends to reduce possibly excessive conservatism which would otherwise be present, particularly in the context of load redistribution resulting in load combinations not seen in the applied loads (L_{H}). For example, in many scenarios, shear capability is symmetric, allowing the load envelope to be expanded to account for shear capability in two opposite directions, thereby expanding the load envelope used to compare with L_{D} values as described with respect to box 212. Additionally, in many scenarios, structures have as much tension capability as compression, so the tensile capability in a given load combination can also be inferred based on the compression capability in given load scenario, further expanding the load envelope and generating a broadened load envelope.

With continued reference to FIG. 3, once the MS_{D} values for each undamaged component are generated, if any undamaged component has a negative MS_{D} under the analysis above, it is assumed in the analysis that the undamaged component could fail under load. As such, the remaining neighbors will be expected to carry increased load of the damaged component(s) and any undamaged but negative margin components. In the event of a negative MS_{D}, the MS_{D} analysis can be re-run for the other undamaged components with the offending un-damaged but negative margin component(s) removed (in order to assume that no load can be carried by the undamaged component due to the expected failure in the load re-distribution scenario). The method 200 includes re-determining the post-damage loads (L_{D}) for the at least one undamaged component when one or more of the initial MS_{D} values for at least one other undamaged component is negative to generate at least one updated MS_{D} value based on the re-determined post-damage loads (L_{D}), as shown schematically by box 216. Re-determining the post-damage loads (L_{D}) includes using a FEA model that reattributes a load that would have been carried by one or more of the damaged components and one or more of the undamaged components having negative initial MS_{D} values to at least one of the undamaged components that had positive initial MS_{D} values. Re-determining the post-damage loads similarly includes generating several hundred or more load cases for a given undamaged component to come up with multiple post-damage load values for each of the undamaged components that had positive initial MS_{D} values. Steps indicated schematically by boxes 210-213 can be performed again with the re-determined post-damage loads.

Once positive MS_{D} values are obtained for all un-damaged and positive margin components in the structure, the SHI can be determined. The SHI is intended to provide the maintainer with actionable information about the structural health of an aircraft zone in a damage tolerant, redundant (multiple load paths) assembly, e.g. a composite aircraft assembly. A zone refers to a significant aircraft assembly, e.g. the cabin section or tail pylon, for example.

The method 200 includes determining the SHI of a given aircraft assembly based on the MS_{D} value for the at least one undamaged component, as indicated schematically by box 218. Determining the SHI of the aircraft assembly includes determining a component contribution parameter “Z” for at least one component of the aircraft assembly based on the MS_{D} value for that component, as indicated schematically by box 220 (per the left hand curve in Chart 1). For each component in the assembly, the component contribution parameter is computed according to the left hand curve in Chart 1, below. For component margin of safety less than zero, the component contribution parameter is 1.0. For “sufficiently high” MS_{D} values, the component contribution parameter is zero. A linear relationship is assumed between MS_{D}=0 and the cutoff point indicated by the green arrow in the figure. This “sufficiently high” margin cutoff point is a tunable parameter, based on durability, risk tolerance, degree of conservatism required for the particular assembly.

Chart 1 shows a calculation of component contribution parameter ‘Z’ given MS_{D} (left) for each component, and calculation of resulting assembly MS adjustment factor given the sum of the component contribution parameters ‘Z’ (right). These relationships represent an intermediate step to computing SHI. The curve shapes can be tuned as desired.

Determining the SHI of the aircraft assembly includes summing the component contribution parameters for the components of the aircraft assembly, shown schematically by box 222. Determining the SHI of the aircraft assembly includes determining an Adjustment Factor by comparing the sum of the component contribution parameters for the components of the aircraft assembly to pre-determined reference values, as indicated schematically by box 224 (per the right hand curve in Chart 1). The Adjustment Factor is a function of the sum of the component contribution parameters for the components computed according to Equation 3 below and represented by the right hand curve in Chart 1, above. The parameters A and k are tunable parameters that modify the curve shape shown in the right hand curve of Chart 1. Parameter A is a predefined asymptotic value for the Adjustment Factor and k is the rate at which the Adjustment Factor approaches A as a function of the summed value of component contribution parameter “Z” for one or more components. A single value of Adjustment Factor is returned for the entire assembly.

$$Adjustment Factor = \frac{2 A}{1 + {e}^{- k Σ Z}} - A \qquad Equation 3$$

The Adjustment Factor acts to quantify the fact that multiple components with low margins of safety result in higher risk to the assembly than a single component with low margin, which would otherwise be lost if the analysis simply used the minimum positive component MS_{D} value for the margin of safety for the assembly.

Determining the SHI of the aircraft assembly includes determining an adjusted Margin of Safety (MS_{A}) for the aircraft assembly by subtracting the Adjustment Factor from the minimum positive MS_{D} value for the components of the aircraft assembly, as indicated schematically by box 226, and as shown by Equation 4 below:

MS_{A}=min(MS_{D})−Adjustment Factor Equation 4

As shown notionally by Equation 4, the MS_{A} of the aircraft assembly is a function of two key factors: the absolute lowest positive MS_{D} value out of all the un-damaged components in the assembly that were used to generated the adjustment factor and the adjustment factor. In addition to the very lowest positive MS_{D} value, the MS_{A} for the aircraft assembly takes into account the presence of other low MS_{D} values in the assembly. In this way, the overall SHI for the assembly (which is a function of MS_{A}) is penalized when more than one component has a reduced MS_{D} value compared to the healthy or as-designed condition. Determining the SHI of the aircraft assembly includes comparing the MS_{A} for the aircraft assembly to pre-determined reference values, as indicated schematically by box 226 and by Equation 5, below.

SHI=f(MS_{A}) Equation 5

To determine the SHI, the MS_{A} for the aircraft assembly is mapped to a 0-1 SHI scale using predetermined reference values, examples of the pre-determined reference values are represented by Chart 2, below. The mapping is performed according to the curve shown in Chart 2. By definition, for a structural assembly in pristine condition, SHI is 0.0. For an assembly level adjusted margin less than zero, SHI is nominally 1.0 (requires repair “now”). Repair could be recommended for SHI value exceeding 0.8, for example. The adjustable repair threshold is an operational decision; it is not part of the SHI computation procedure. For sufficiently high assembly level adjusted margin, the SHI would be zero meaning that the structure can carry its intended design loads. Between the two bounds for adjusted margins there is an application- or platform-specific gray scale mapping for SHI according to the curve.

Chart 2 is a function to map the MS_{A} for the assembly to SHI between 0.0 and 1.0. The curve shape can be tuned to meet the needs of a specific platform or desired maintenance environment (e.g. wartime vs peacetime, etc.).

The method 200 includes displaying a repair indicator on a graphical user interface (GUI), e.g. the GUI 34, if the SHI exceeds a pre-determined threshold, as indicated schematically by box 228. This can include continuously updating and displaying a status indicative of the SHI on GUI. SHI can be displayed/reported through the GUI or another means in a number of ways. First, SHI can be discrete, as shown in Table 1, below, where the SHI value is binned into some small number of well-defined categories and then an indicator (e.g. a green, yellow or red light) can be used to signal the status to a user. Alternatively, SHI can be reported as a continuous number between zero and one, where 0.0 is pristine and 1.0 means the structure can no longer carry the required loads. The SHI value is a strong function of the margin of safety of the components that comprise the assembly, particularly the minimum margin of safety. Having the ability to show various “shades” of green, yellow, or red rather than limiting to three bins may be desirable to provide additional insight into the remaining capability, particularly when the SHI is “yellow”. When the structure is in the “watch” condition, it may be useful to estimate how long until a repair becomes necessary, and whether the structure is still capable of severe missions.

It is also contemplated that the corresponding levels can have an engineering definition rooted in residual strength characterized by margin of safety, also as shown in Table 1.

TABLE 1
Potential Discrete SHI Definitions

| SHI | Maintenance Interpretation | Engineering Definition |
|---|---|---|
| Green | No action | All component MS_{D} values > 0 |
| Yellow | Watch | 1 or more component MS_{D} |
| | | value < 0 and assembly MS_{A} > 0 |
| Red | Repair | assembly MS_{A} < 0 |

The methods and systems of the present disclosure, as described above and shown in the drawings, provide for structural health assessment systems and methods with superior properties including, for example, the ability to distinguish damaged airframes that are safe to fly from damaged airframes that require repair. While the apparatus and methods of the subject disclosure have been shown and described with reference to preferred embodiments, those skilled in the art will readily appreciate that changes and/or modifications may be made thereto without departing from the scope of the subject disclosure.

What is claimed is:

1. A method of assessing structural health in a multi-load-path assembly, comprising:
determining a Margin of Safety (MS_{H}) value for at least one of a plurality of components in an assembly when the assembly is healthy;
determining if damage to the assembly has occurred;
determining a Margin of Safety (MS_{D}) value for at least one undamaged component of the plurality of components in the assembly when the assembly is damaged, if damage to the assembly has occurred; and
determining a Structural Health Index (SHI) of the assembly based on the MS_{D} value for the at least one undamaged component.

2. The method as recited in claim 1, wherein determining the MS_{H} value for the at least one of the plurality of components includes comparing an allowable load for the at least one of the plurality of components to the applied load for the at least one of the plurality of components, wherein the applied load is determined through the use of an finite element analysis (FEA) model.

3. The method as recited in claim 1, wherein determining the MS_{D} value for the at least one undamaged component includes scaling its MS_{H} value based on increased loads due to the load redistribution with the following equation:
$$M {S}_{D} = ( M {S}_{H} + 1 ) \frac{{L}_{H}}{{L}_{D}} - 1$$
where L_{H} is a baseline load on the undamaged component before the load redistribution, and where L_{D} is a post-damage load on the at least one undamaged component after the load redistribution.

4. The method as recited in claim 3, further comprising determining the post-damage load (L_{D}) for the at least one undamaged component by using a finite element analysis (FEA) model that reattributes a load that would have been carried by one or more of the damaged components to the at least one undamaged component.

5. The method as recited in claim 4, wherein determining the post-damage load (L_{D}) for the at least one undamaged component includes considering a plurality of load cases for each undamaged component and generating a load envelope for each undamaged component using a plurality of baseline loads (L_{H}) acting on the undamaged component before the load redistribution.

6. The method as recited in claim 5, wherein generating the load envelope for each undamaged component includes expanding the load envelope using pre-determined rules to generate a broadened load envelope.

7. The method as recited in claim 4, further comprising re-determining the post-damage load (L_{D}) for the at least one undamaged component when one or more of the initial MS_{D} values for at least one other undamaged component is negative to generate at least one updated MS_{D} value based on the re-determined post-damage load (L_{D}).

8. The method as recited in claim 7, wherein re-determining the post-damage load (L_{D}) includes using a FEA model that reattributes a load that would have been carried by one or more of the damaged components and one or more of the undamaged components having negative initial MS_{D} values to at least one of the undamaged components that had positive initial MS_{D} values.

9. The method as recited in claim 1, wherein determining if damage to at least one of the plurality of components has occurred includes receiving a strain measurement from a sensor coupled to at least one of the plurality of components of the assembly.

10. The method as recited in claim 1, wherein determining if damage to at least one of the plurality of components has occurred includes visually inspecting at least one of the plurality of components.

11. The method as recited in claim 1, further comprising displaying a repair indicator on a graphical user interface (GUI) if the SHI exceeds a pre-determined threshold.

12. The method as recited in claim 1, further comprising continuously updating and displaying a status indicative of the SHI on a graphical user interface (GUI).

13. The method as recited in claim 1, wherein determining the SHI of the assembly includes determining a component contribution parameter for at least one component of the assembly based on the MS_{D} value for that component.

14. The method as recited in claim 13, wherein determining the SHI of the assembly includes summing the component contribution parameters for the components of the assembly.

15. The method as recited in claim 14, wherein determining the SHI of the assembly includes determining an adjustment factor by comparing the sum of the component contribution parameters for the components of the assembly to pre-determined reference values.

16. The method as recited in claim 15, wherein determining the SHI of the assembly includes determining an adjusted Margin of Safety (MS_{A}) for the assembly by subtracting the adjustment factor from the minimum positive MS_{D} value for the components of the assembly.

17. The method as recited in claim 16, wherein determining the SHI of the assembly includes comparing the adjusted Margin of Safety for the assembly to pre-determined reference values.

18. A structural health assessment system for a multi-load-path assembly, the system comprising:
a plurality of assembly components;
at least one sensor operatively connected to at least one of the plurality of components to capture damage-indicating data for at least one of the plurality of assembly components;
a processor in operative communication with at least one of the sensors to receive damage-indicating data therefrom; and
a memory in operative communication with the processor having program instructions for determining structural health of an assembly, the program instructions being executable by the processor to:
determining a Margin of Safety (MS_{H}) value for at least one of a plurality of components in an assembly when the assembly is healthy;
determining if damage to the assembly has occurred based on the damage-indicating data from the at least one sensor;
determining a Margin of Safety (MS_{D}) value for at least one of the plurality of components in the assembly when the assembly is damaged, if damage to the assembly has occurred; and
determining a Structural Health Index (SHI) of the assembly based on the MS_{D} value for the at least one undamaged component.

19. A system as recited in claim 18, further comprising a GUI operatively connected to the processor to receive data therefrom, wherein the GUI displays a repair indicator if the SHI exceeds a pre-determined threshold.

20. A system as recited in claim 18, further comprising a GUI operatively connected to the processor to receive data therefrom, the GUI continuously displays a status indicative of the SHI based on continuously updated real-time data from the processor.
